(19) United States
(12) Patent Application Publication
(10) Pub. No.: US 2007/0257686 A1
(43) Pub. Date: Nov. 8, 2007

(54) INTEGRATED CIRCUIT PROBE CARD ANALYZER

(76) Inventor: Oscar Beijert, MJ Zwaag (NL)

Correspondence Address: PATTERSON & SHERIDAN, L.L.P., 3040 POST OAK BOULEVARD, SUITE 1500, HOUSTON, TX, 77056, US

(21) Appl. No.: 11/743,020

(22) Filed: May 1, 2007

Related U.S. Application Data
(60) Provisional application No. 60/746,117, filed on May 1, 2006.
(60) Provisional application No. 60/889,125, filed on Feb. 9, 2007.

(51) Int. Cl. G01R 31/02

(52) U.S. Cl. 324/754

(57) ABSTRACT

Methods and apparatus for use in analyzing probe cards are provided. For some embodiments, chucks with particular materials selected to achieve desired properties, such as improved conductivity, robust viewing windows, and the like, are provided. For other embodiments, useful features, such as force measurements for probe pins may be provided. For still other embodiments, improved flipping tables or features thereof may be provided.

### CROSS-REFERENCE TO RELATED APPLICATIONS

This application claims benefit of U.S. Provisional Patent Application Ser. Nos. 60/746,117 filed May 1, 2006 and 60/889,125 filed Feb. 9, 2007, both of which are herein incorporated by reference in their entirety.

### BACKGROUND OF THE INVENTION

1. Field of the Invention

Embodiments of the present invention generally relate to integrated circuit testing, and more particularly, to a method and apparatus for testing probe cards used to test integrated circuits on a wafer.

2. Description of the Related Art

Probe card test and verification systems are commonly used as production tools for the characterization of probe cards (used in testing integrated circuit devices/substrates) before and after use and to facilitate rework of probe cards which do not conform to predefined standards. Such systems typically consist of a computer, a precision measurement system, a software based vision system, and precision motion control and measurement system. Such equipped systems allow for the measurement and adjustment of probe card planarization, visual X/Y location and adjustment, Probe contact resistance, leakage and component measurements.

Electrical parameters including contact resistance and leakage may also measured against reference values and an indication may be provides as to whether a probe card assembly under test has passed or failed. If a failure is determined, a full report may be printed to accompany the card for rework. Quick verification provided by such systems may validate that a probe card assembly is ready for test or is in need of rework.

There is a continuing need to improve such systems, for example, by adding new features, increasing performance and robustness.

### SUMMARY OF THE INVENTION

Embodiments of the present invention provide methods and apparatus for use in analyzing probe cards.

For some embodiments, chucks with particular materials selected to achieve desired properties, such as improved conductivity, robust viewing windows, and the like, are provided.

For some embodiments, useful features, such as force measurements for probe pins may be provided.

For some embodiments, improved flipping tables or features thereof may be provided.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a picture of a portion of a probe card analyzer, zoomed in to show the chuck and the camera window, according to embodiments of the invention;

FIGS. 1A-B are pictures of the chuck illustrating areas uncoated and coated with a conductive ceramic material, according to embodiments of the invention;

FIG. 2A is a computer-aided design model of a portion of a probe card analyzer, detailing the chuck, the optical window, and the probe friction force measurement system, according to embodiments of the invention;

FIG. 2B is a computer-aided design model of the probe friction force measurement system showing two separated sections, according to embodiments of the invention;

FIG. 2C is a computer-aided design model of the probe friction force measurement system, zoomed into to show the pin insert and the two force sensors, according to embodiments of the invention;

FIGS. 3A-B are pictures of a portion of a probe card analyzer, zoomed in to show a block containing the light source with and without the chuck disposed above the light source, according to embodiments of the invention;

FIG. 4 is a mechanical schematic of the components of the flipping table, according to one embodiment of the invention;

FIG. 5 is a mechanical schematic with dimensions of one carbon fiber sheet composing the flipping table sandwich, according to one embodiment of the invention;

FIGS. 6A-D are computer-aided design models of the flipping table and automatic balancing counter weight in a 180° rotation sequence, according to embodiments of the invention;

FIG. 7 is a prior art image of a camera window comprising sapphire, portraying scratches in the window;

FIGS. 8A-D are design drawings of a probe repair tool, according to embodiments of the invention; and

FIGS. 9A-C are pictures of a z stage and a line scanner mounted on an x stage of a probe card analyzer, according to embodiments of the invention.

### DETAILED DESCRIPTION

Embodiments of the invention provide for a probe card analyzer used for testing integrated circuit probe cards.

### An Exemplary Probe Card Analyzer Chuck

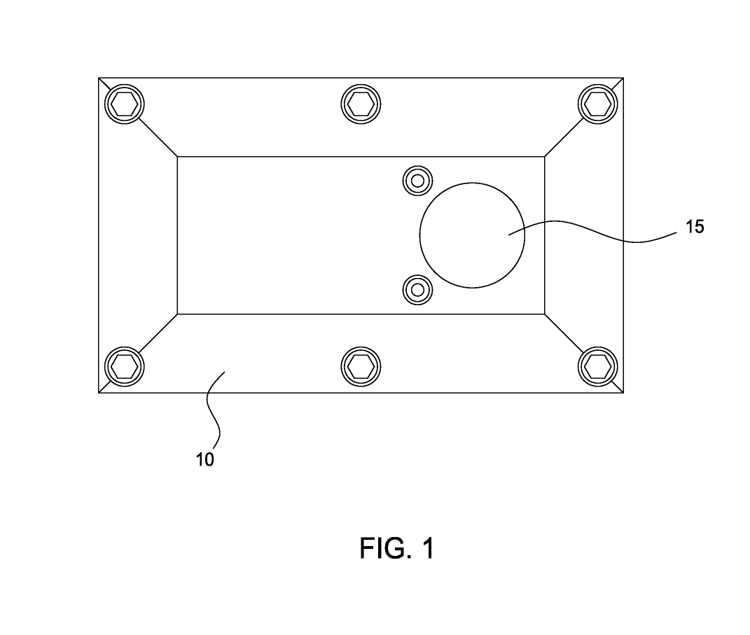

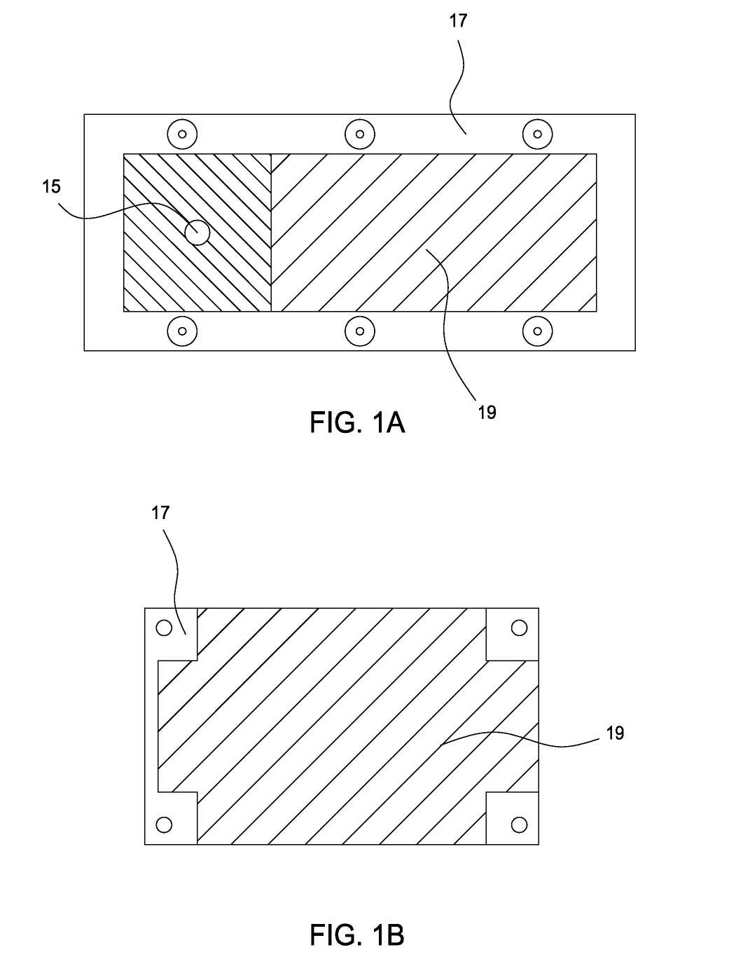

FIG. 1 is a picture of a portion of a probe card analyzer, zoomed in to show a chuck 10, which may hold the probe card under test (not shown). For some embodiments, the chuck 10 may comprise a special conductive ceramic coating, such as TiN. Being a hardened material, this ceramic coating may provide extended life for the chuck 10. For some embodiments, the grain size of the ceramic coating can be manufactured to be 1 micron, thereby achieving a roughness to replicate real silicon wafer bonding pads. The base of the chuck 10 may comprise nickel, and the ceramic coating may be sputtered on. The upper surface of the chuck 10 may have a polished area for testing other aspects of the probe card. Different sizes of the chuck 10 may be available for testing different sized wafers, and some versions of the chuck 10 may allow for verifying probe cards at extended temperatures, such as 125° C.

A transparent camera window 15 may be used to view the probe pins. Images of probe pin locations at first (e.g., zero force) and second (predefined pressure to simulate actual use in testing) contact forces may be captured to determine “scrub marks” indicating where a probe pin will contact a device during test. Such scrub marks may be analyzed to determine of adjustment or rework is necessary to ensure the corresponding probe pins will contact a desired pad during testing.

As illustrated in FIG. 1A, for some embodiments, the chuck 10 may comprise a section 19 with a conductive ceramic material coated thereon (e.g., sputtered on), while portions 17 may be left uncoated. For some embodiments, the uncoated portions 17 may include the transparent camera window 15 as depicted in FIG. 1A. A larger chuck is shown in FIG. 1B, where corner portions 17 may be left uncoated. For some embodiments, the base of the chuck may be ceramic that is specially treated to allow for sputtering. The uncoated areas may accommodate mounting of the window for the camera function to take the air and scrub images used in the probe card analysis. The larger chuck may accommodate multiple cameras (e.g., four) and may have a larger number of isolated dots (e.g., sixteen).

Multiple isolated dots that are sufficiently close to each other may allow for rapid identification of probe pin electrical characterization. For example, the electrical characterization may include which channel and from which coordinate a probe should be referenced to from a reference list. This may reduce an amount of motion stepping conventionally needed for such characterizing and, therefore, speeding tests.

For some embodiments, air and scrub image(s) may be used for finding the X/Y location concerning the related scrub marks. For example, when a scrub mark direction does not relate to the probe position, it may indicate that there is a malfunction of a probe card and/or motherboard (e.g., the test fixture of the probe card). To detect such instances, the system may be able to measure the difference between the air and scrub position in relation to a predetermined probe angle, for example, loaded from a reference file. This solution may lead to faster testing and also less wearing for the probe card.

Referring back to FIG. 1, for some embodiments, the camera window 15 may be part of the chuck 10, as illustrated in FIG. 1. The camera window 15 may comprise diamond or diamond-like carbon because of their scratch-resistant properties in an effort to secure a long life. In fact, a camera window comprising either of these two materials may never need to be replaced, thereby avoiding maintenance costs. Diamond and diamond-like carbon may also provide a clearer view over conventional camera windows comprising sapphire.

### An Exemplary Probe Friction Force Sensor

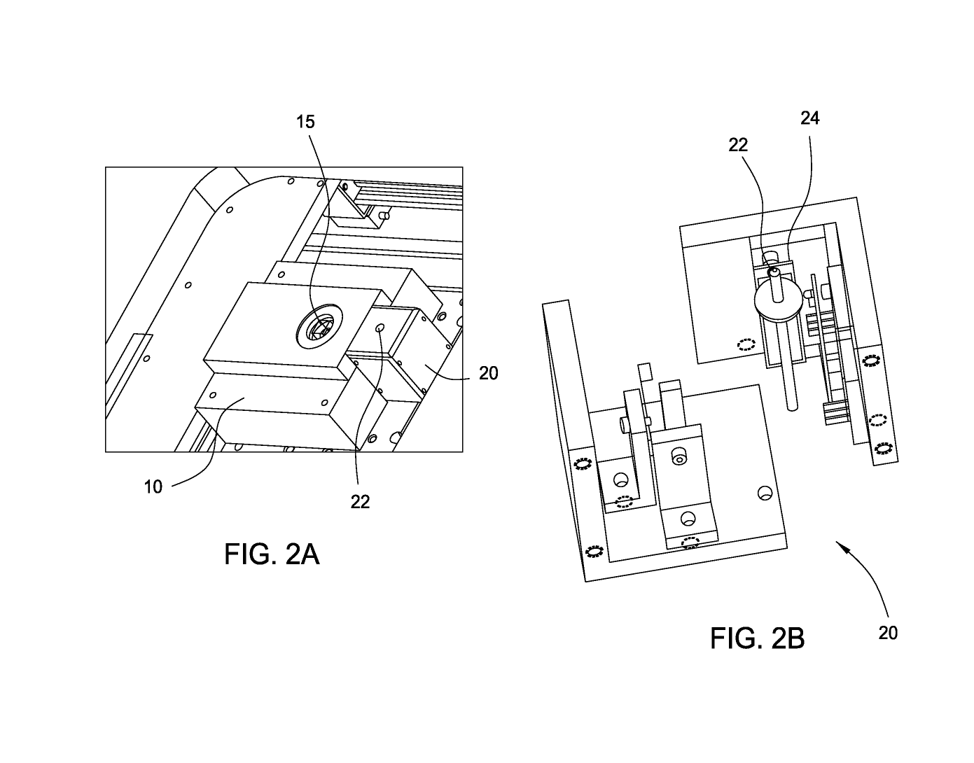

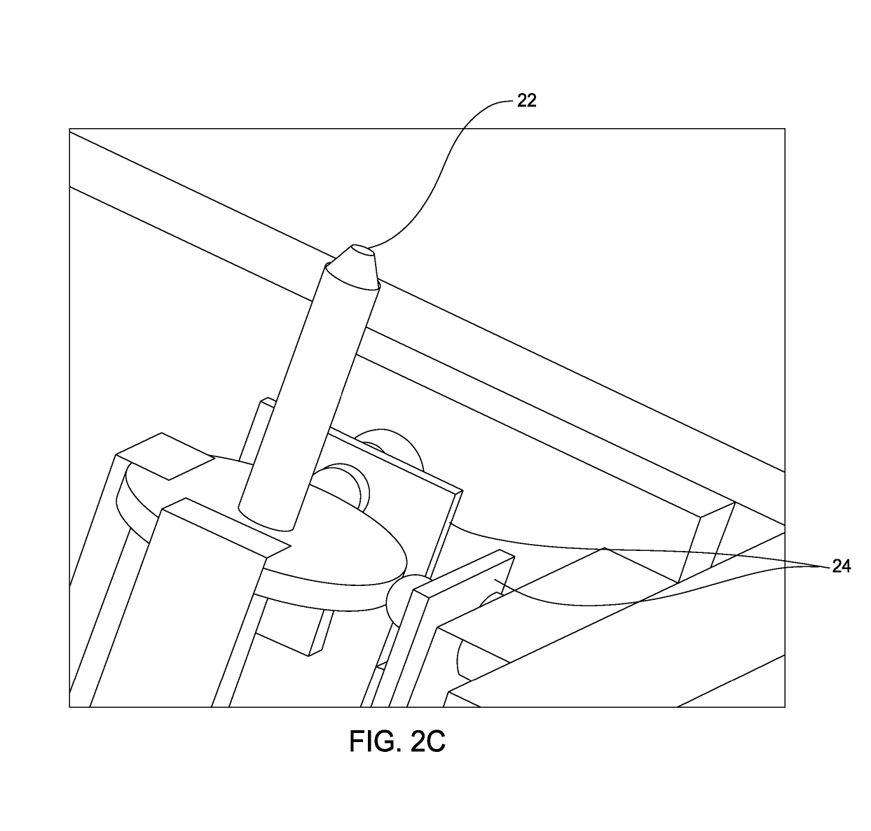

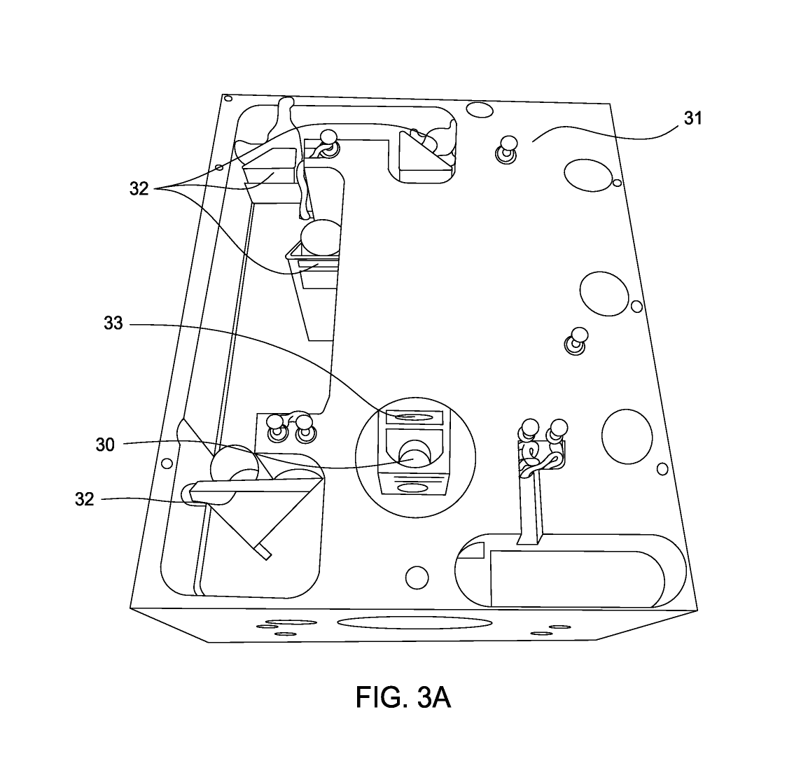

For some embodiments, a probe friction force measurement system 20 may be attached to the chuck 10, as shown in the computer-aided design model of FIG. 2a. The probe friction force measurement system 20 may be used to measure the resistance a probe pin experiences when pushed into a planar surface to make a scrub mark. This measurement may be used to measure the life expectancy of an individual probe or the entire probe card as the forces tend to get weaker with age. The details of this system 20 may be seen more clearly in FIGS. 2b and 2c, which show a pin insert 22 and two force sensors 24 placed perpendicularly to measure the force in two different axes, according to some embodiments. Because the pin insert 22 can be replaced with inserts comprising any suitable material, the probe friction force measurement system 20 may be used to measure the differences between sliding over materials used in the camera window, such as glass, sapphire, diamond, and diamond-like carbon, and materials used on the actual semiconductor wafer bonding pads, such as aluminum. With these different measurements, the system 20 may be used to measure the resistance force on real aluminum pads and subsequently set the corresponding test limits for measurements on the camera window 15 of the probe card analyzer.

### An Exemplary Light Source

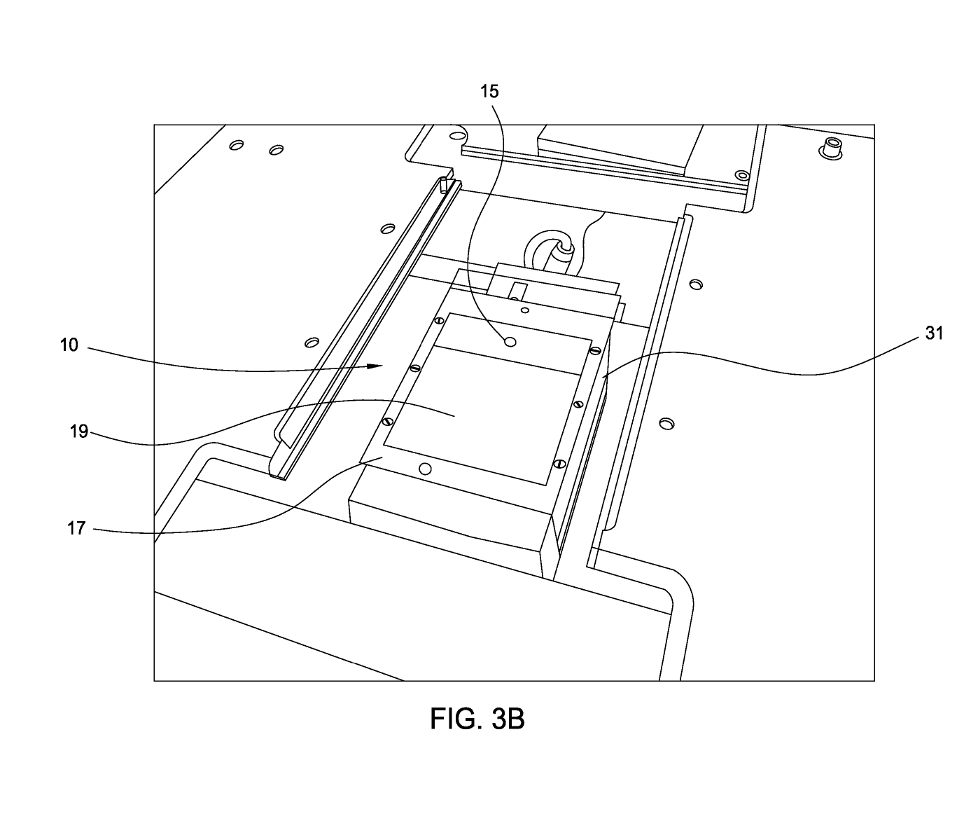

To view the probe card pins through the camera window 15 of the probe card analyzer, a constant light source with high contrast may be used. FIG. 3A illustrates a portion of a probe card analyzer, zoomed in to show a block 31 containing a light source 30 disposed therein. For some embodiments, the light source 30 may comprise a light source designed to provide high contrast. For example, the light source 30 may comprise a monochromatic blue-green light-emitting diode (LED) possessing a wavelength between 498 nm and 513 nm. This wavelength range may provide a high contrast light for viewing probe card pins. In addition, since this blue-green LED may be very stable, the illuminating wavelength should change little over time. As a result, there should not be a need for frequent recalibration of the probe card analyzer. The light source 30 may also comprise a lens, mirrors 32 and a beam splitter cube 33. The beam splitter cube 33 may possess a certain wave reflection in an effort to minimize polarization. FIG. 3B illustrates the chuck 10 overlying the block 31 and covering the light source 30, which may illuminate the probe card pins through the window 15.

### An Exemplary Flipping Table

An automatic flipping table 35 may support the probe card while it is being imaged and tested, and then it may rotate 180°, or flip over, in a controlled manner (e.g., using pneumatics upon an operator request) so that the probe pins or other aspects of the probe card may be reworked. After a rework, the flipping table 35 may easily be reverted back to its original position to continue testing without ever having to realign the probe card.

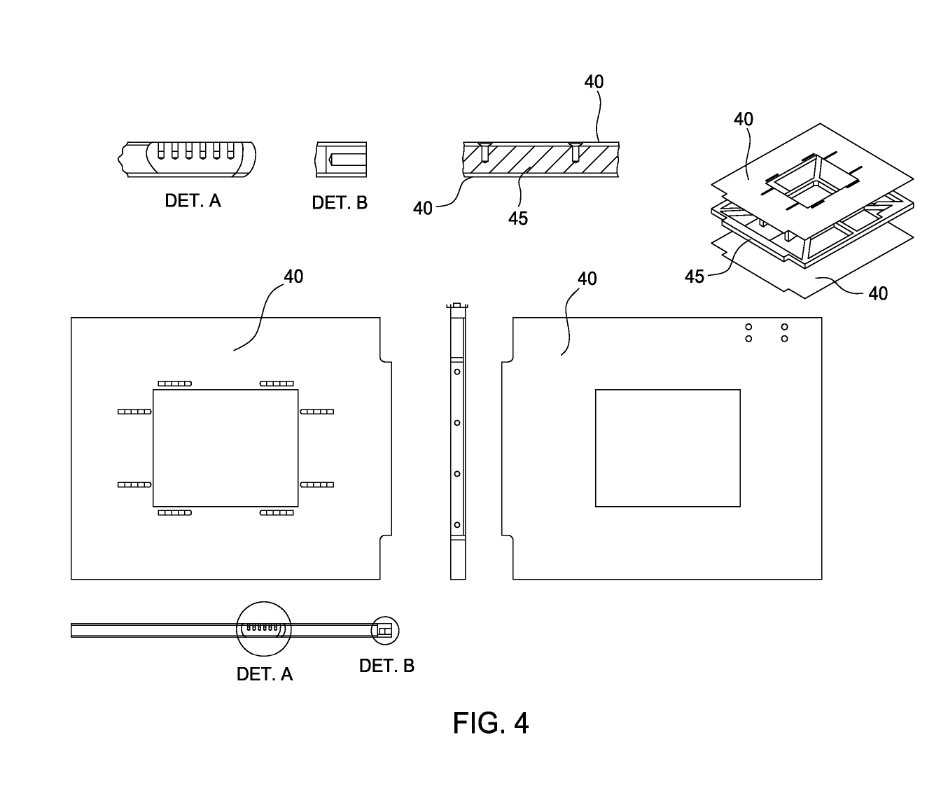

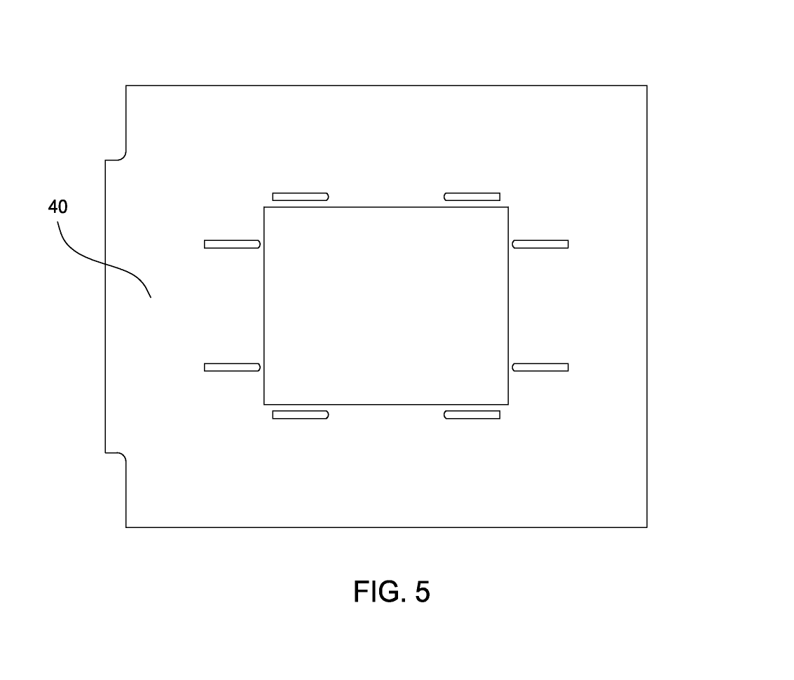

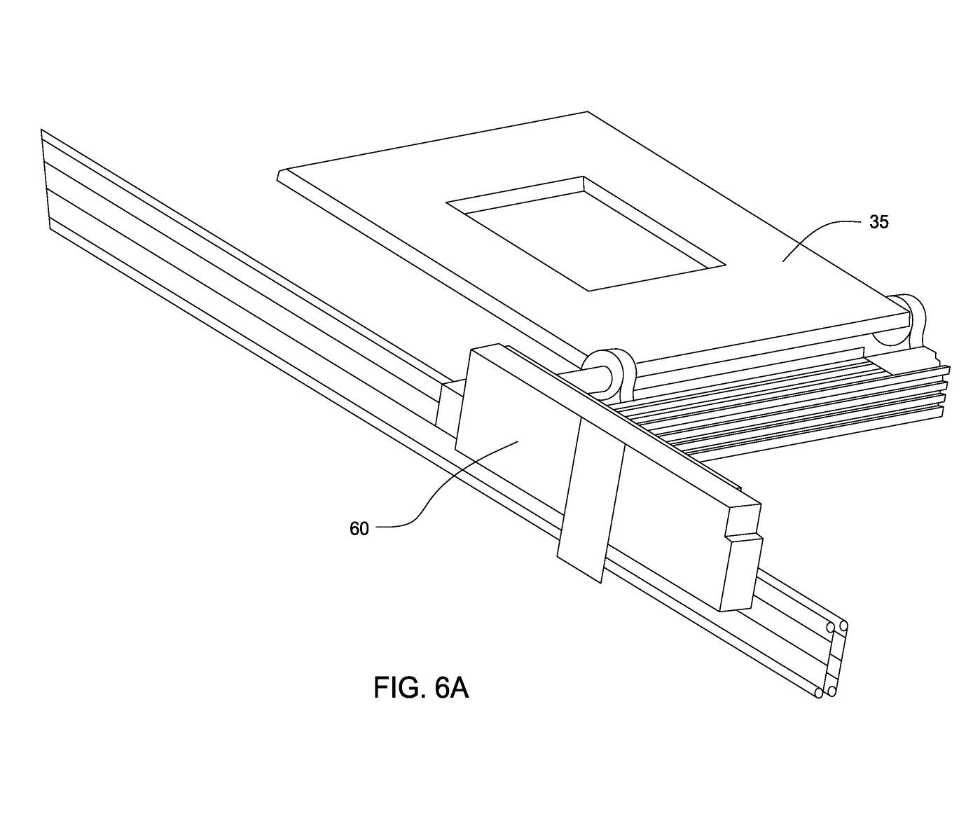

In an effort to assist in this function, the flipping table 35 may be composed of a lightweight, yet strong and stable material. As such, the flipping table 35 may comprise a sandwich of two carbon fiber sheets 40 interposed by an aluminum frame 45 as shown in the mechanical schematic of FIG. 4. An exemplary carbon fiber sheet for some embodiments is shown in FIG. 5 and may have general dimensions of 732 mm×600 mm×31.4 mm.

### An Automatic Flipping Table Counterbalance

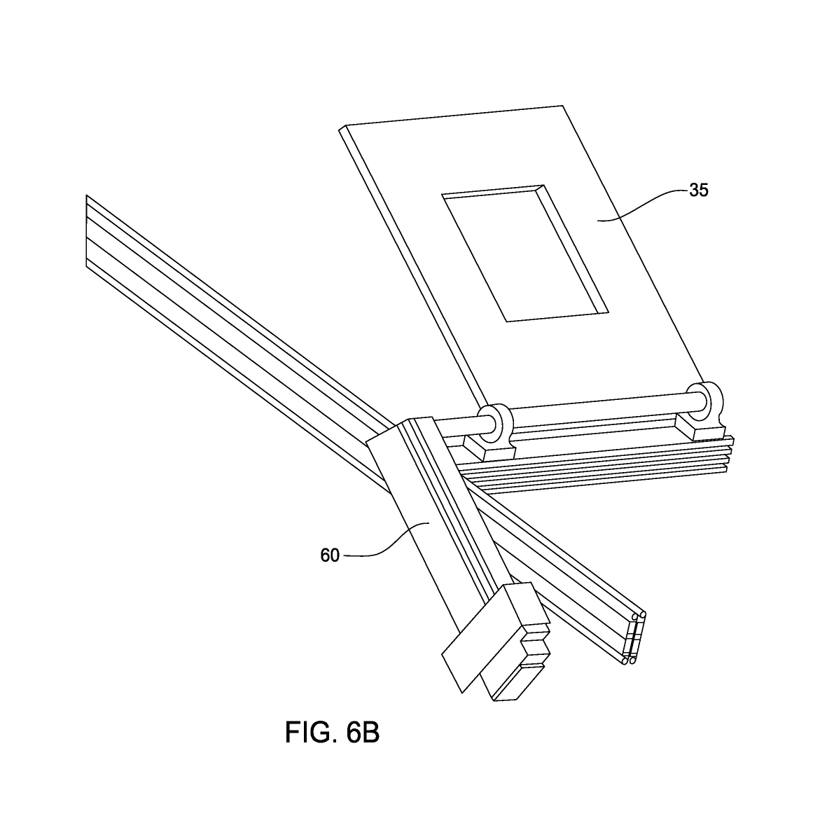

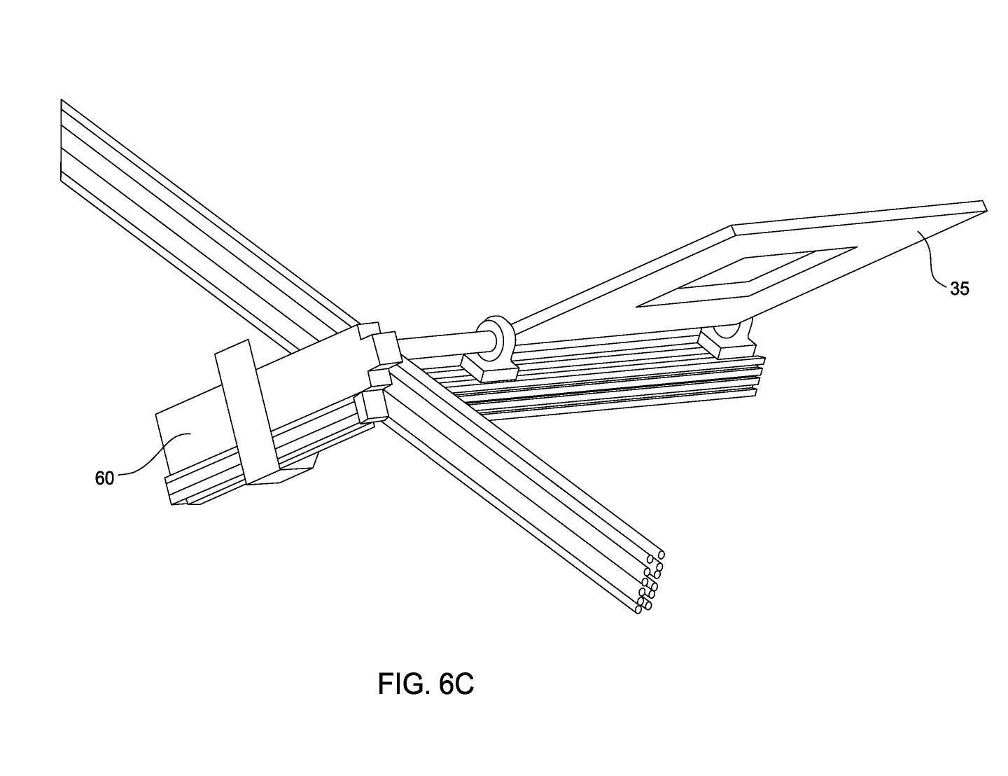

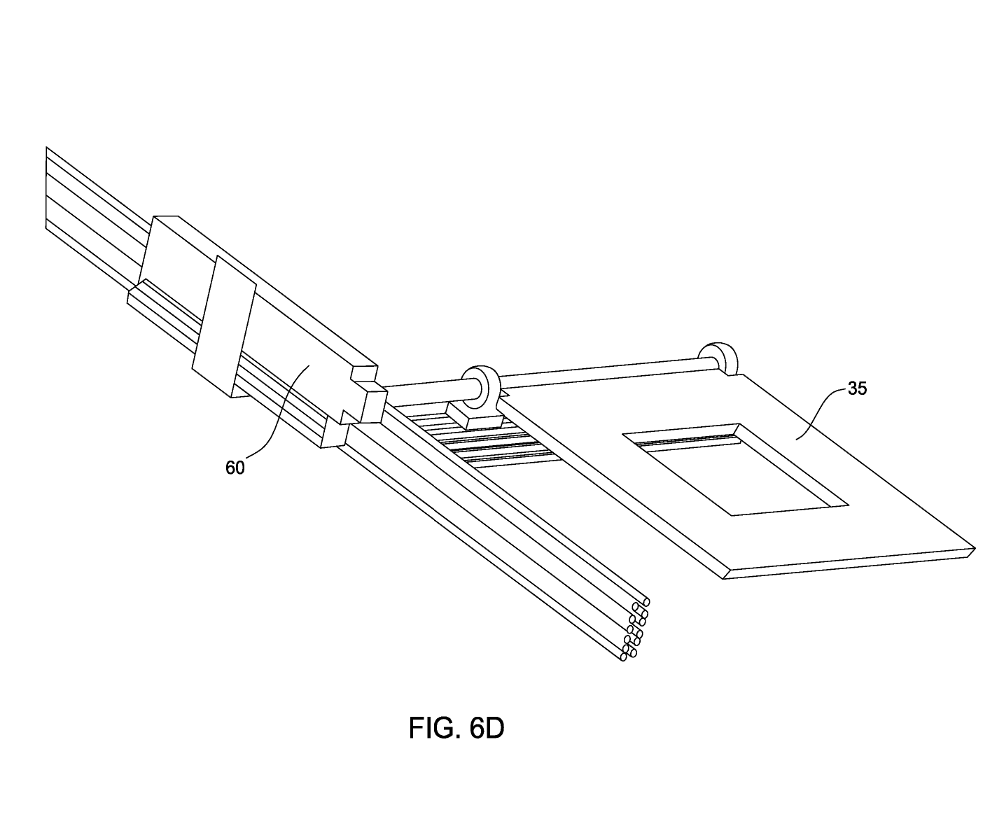

In an effort to counterbalance the weight of the flipping table 35 as it rotates (thereby assisting in an even and controlled motion with little interaction from a user), a counter weight 60 may be utilized as shown in FIG. 6a. The counter weight 60 may be automatically adjusted via software to counterbalance the weight of the flipping table 35 and the probe card. FIGS. 6a-d are computer-aided design models of the flipping table 35 and automatic balancing counter weight 60 in a 180° rotation sequence, according to some embodiments.

### An Exemplary Camera Window

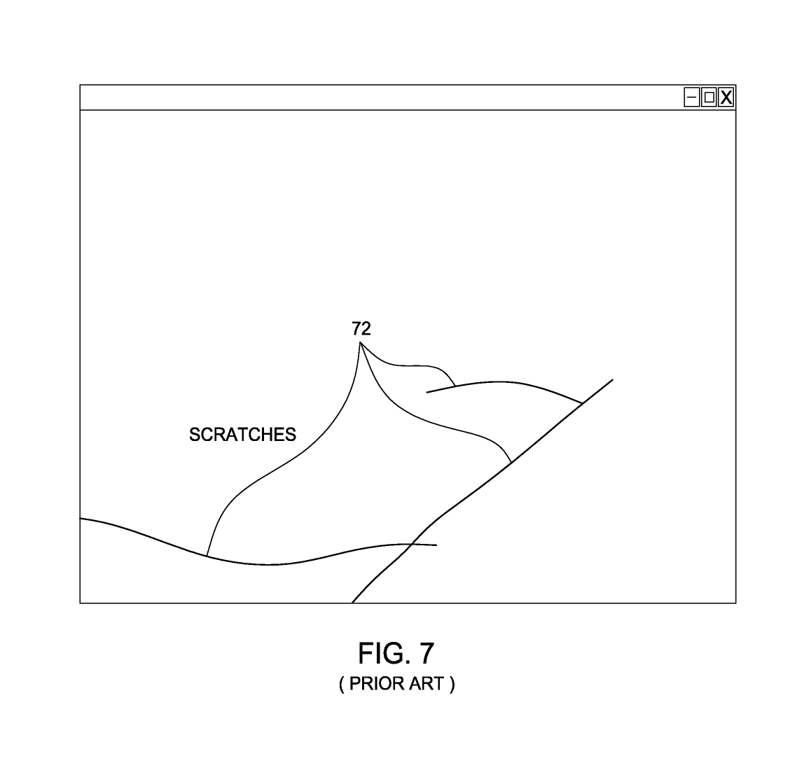

As described above, the camera window made from a diamond material. This material may provide a more clear view than a standard sapphire window. As shown in FIG. 7, sapphire windows may be prone to scratches 72. In addition, a window made from diamond material may have an increased life time. In some cases, the window may not need to be replaced for the life of the system, thereby reducing maintenance costs. For some embodiments, the diamond material may be a synthetic type A1 material, which would result in one of the hardest windows in the world.

For some embodiments, a 3-D camera system for fast detection may be utilized. For example, such a system may be configured to measure planarity and alignment in one movement. For non-contact, optical planarization (Z measurement), it may be possible to incorporate multiple cameras. For example, there may be two or more cameras measuring a 3-D view and a shadow (identified by the processor via image analysis) may be valid for the Z position (height) after calibrating the shadow length.

### An Exemplary Probe Repair Tool

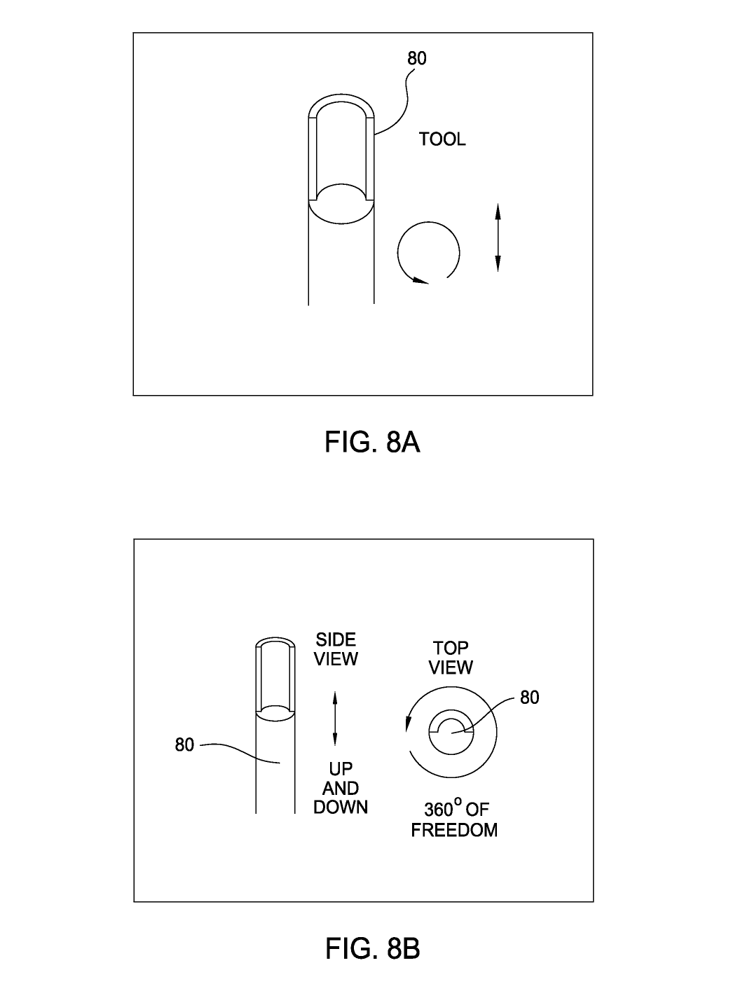

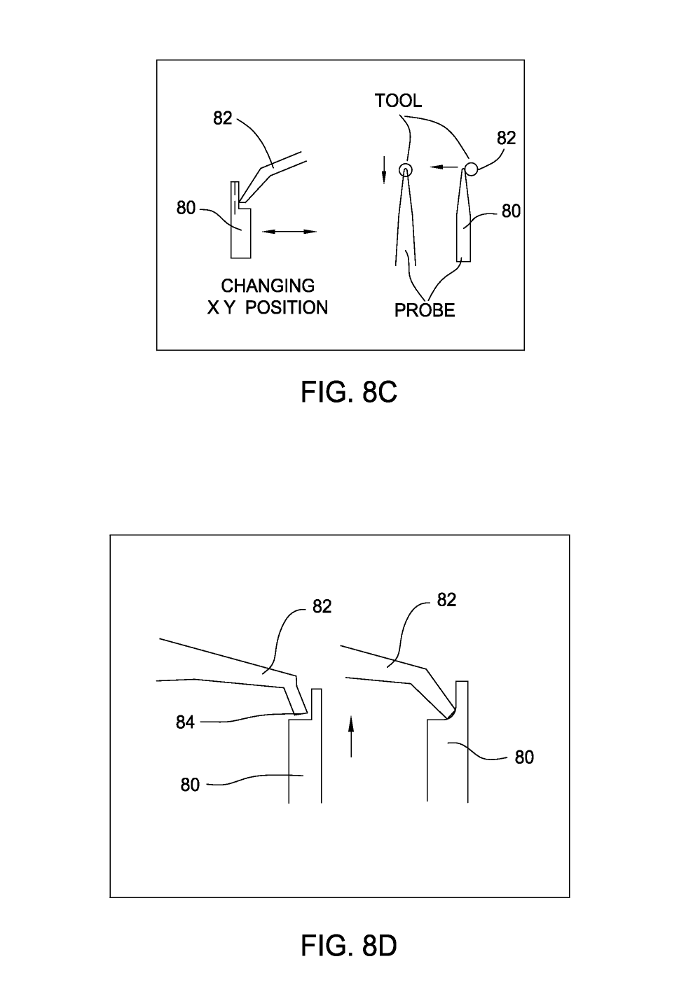

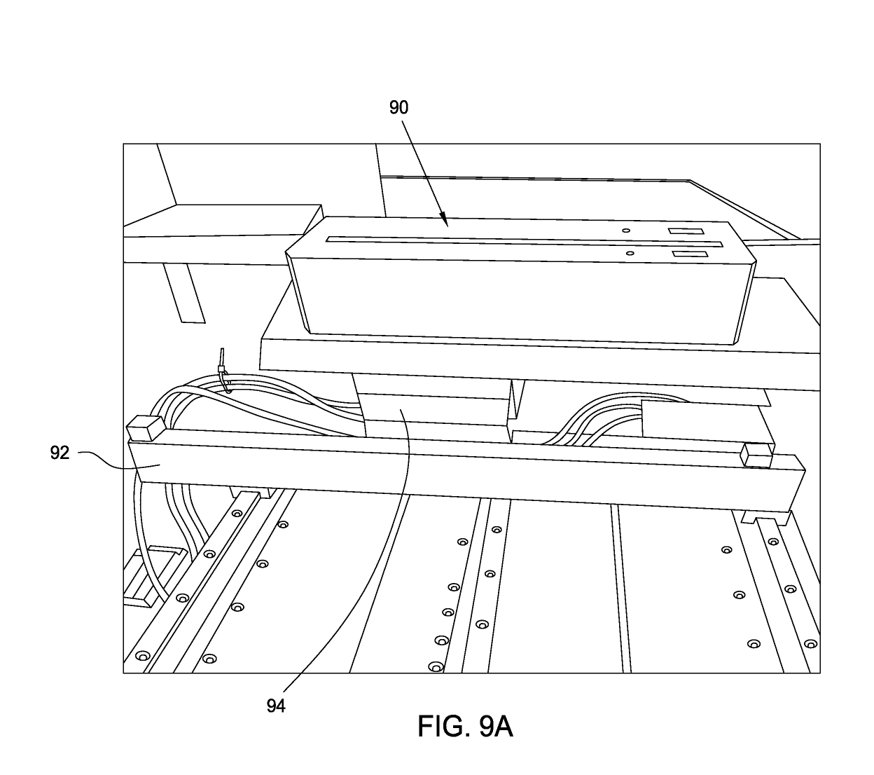

Once a damage probe is detected by the probe card analyzer, a misaligned or bent probe may be repaired by a probe repair tool 80 as illustrated in FIG. 8A. The upper portion of the probe repair tool 80 may be shaped like a small, hollow cylinder cut in half along the longitudinal axis. The bottom portion of the probe repair tool 80 may be a solid rod for robustness. Mounted on the z stage of the probe card analyzer for vertical movement, the probe repair tool 80 may also have a small motor (not shown) coupled to it so that the tool 80 can rotate 360° as illustrated in FIG. 8B.

Because the probe card analyzer knows the direction of the integrated circuit test card probes after recording the air and scrub images, an individual probe 82 may be determined to have a positional error due to a bent probe tip or misaligned probe that should be adjusted to the ideal position. For some embodiments, the ideal position of the probe 82 may be known by the probe card analyzer from a spreadsheet. If a probe 82 is out of position, the probe repair tool 80 may be moved in the X and Y directions using the motors in the X stage and moved vertically using the z stage motor to the present, incorrect location of the misaligned probe 82. Upon reaching the probe 82, the probe repair tool 80 may be rotated such that the receiving position in the upper half of the probe repair tool 80 is facing a desired direction. For instances where the probe 82 should be corrected laterally, the receiving position of the probe repair tool 80 may be rotated to face the corrective lateral direction as illustrated in the side and top views of FIG. 8C. For instances where the probe 82 should be corrected vertically, the receiving position of the probe repair tool 80 may face the arm of the probe 82 as shown in FIG. 8D.

Once the probe repair tool 80 has been positioned under the probe 82 and rotated so that the receiving position is facing the desired direction, the probe repair tool 80 may be moved laterally via the X stage (FIG. 8C), vertically via the Z stage (FIG. 8D), or both either simultaneously or sequentially in an effort to push the probe 82 or probe tip 84 back into the known ideal position. Afterwards, the camera under the diamond window 15 in the chuck 10 may measure the new position of the probe 82, and if the analyzer determines that the probe 82 should be adjusted further, the repair process may be repeated using the probe repair tool 80.

For some embodiments, the probe repair tool 80 may be used as an individual probe cleaner by employing a relatively abrasive cleaning pad adhering to the inner surface of the hollow half cylinder of the upper portion of the tool 80.

### An Exemplary Line Scanner Image Sensor

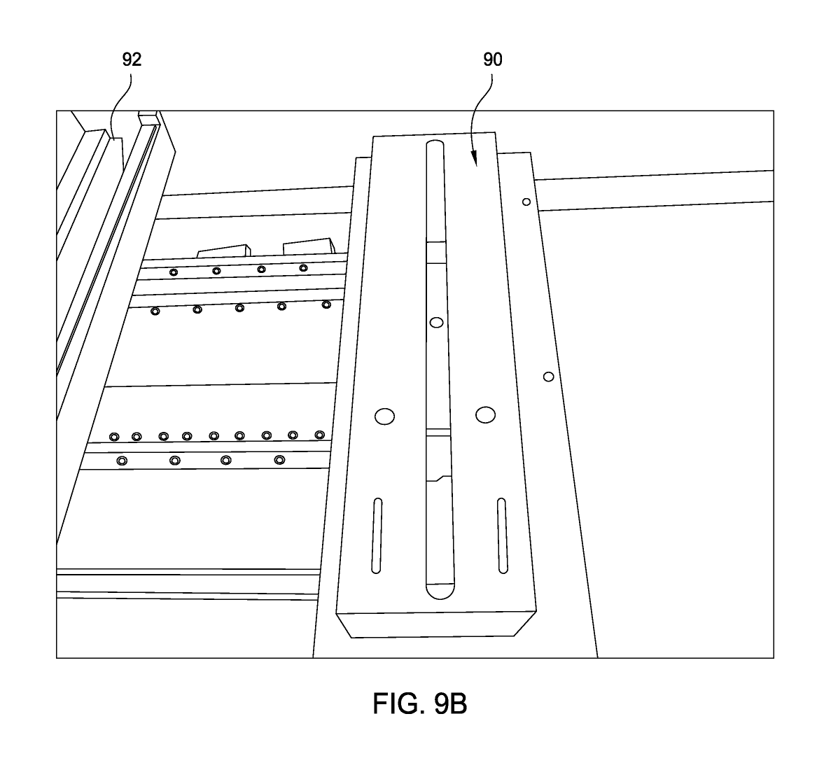

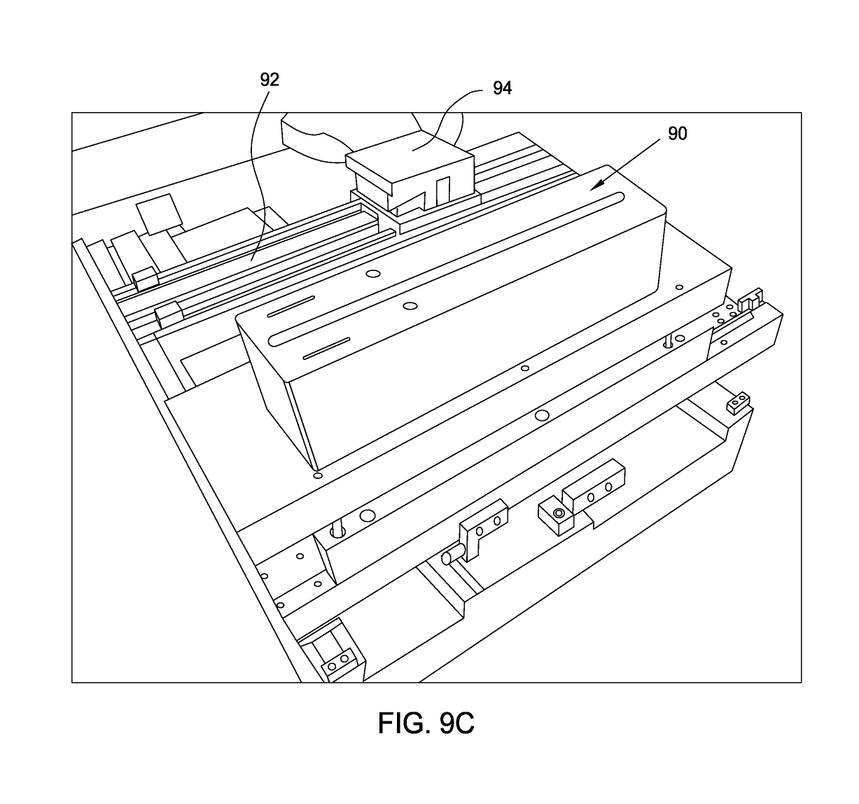

Referring now to FIGS. 9A-C, the probe card analyzer may employ a line scanner image sensor 90 in an effort to quickly image and determine probe positions on high probe count test cards. The image sensor 90 may be mounted on an X stage 92 above a Z stage 94 for vertical movement. Providing images of several probes at one time, the image sensor 90 may comprise a rectangular window composed of glass with a diamond-like carbon (DLC) coating in an effort to prevent scratches on the window. With the Z stage 94, the image sensor 90 can move up and down to determine the air and scrub image(s) position measurements. The X stage 92 provides for lateral movement of the image sensor 90, and the combination may allow the images to be taken from left to right, from right to left, from top to bottom, or from bottom to top.

What is claimed is:

1. An integrated probe card analyzer apparatus, comprising:
a chuck for holding a probe card under test;
a conductive ceramic coating formed on at least a portion of the chuck; and
a transparent window formed in the chuck for viewing probe pins of the probe card under test.

2. The apparatus of claim 1, wherein a grain size of the conductive ceramic coating is designed to replicate the roughness of silicon wafer bonding pads.

3. The apparatus of claim 2, wherein the grain size is approximately 1 micron or greater.

4. The apparatus of claim 1, wherein the conductive ceramic coating comprises at least some percentage of TiN.

5. The apparatus of claim 1, wherein the conductive ceramic coating is sputtered on the chuck.

6. The apparatus of claim 1, wherein the chuck comprises a polished area for testing parameters of the probe card.

7. The apparatus of claim 1, wherein at least a portion of the chuck is not coated with the conductive ceramic coating.

8. The apparatus of claim 1, wherein the chuck comprises a plurality of electrically conductive isolated dots sufficiently close to each other to allow rapid identification of a probe pin electrical parameter.

9. The apparatus of claim 1, wherein the window comprises at least one of a diamond or diamond-like carbon.

10. A chuck for holding a probe card under test by an integrated probe card analyzer, comprising:
a conductive ceramic coating formed on at least a portion of the chuck; and
a transparent window formed in the chuck for viewing probe pins of the probe card under test.

11. The chuck of claim 10, wherein a grain size of the conductive ceramic coating is designed to replicate the roughness of silicon wafer bonding pads.

12. The chuck of claim 11, wherein the grain size is approximately 1 micron or greater.

13. The chuck of claim 10, wherein the conductive ceramic coating comprises at least some percentage of TiN.

14. The chuck of claim 10, wherein the conductive ceramic coating is sputtered on the chuck.

15. The chuck of claim 10, wherein the chuck comprises a polished area for testing parameters of the probe card.

16. The chuck of claim 10, wherein at least a portion of the chuck is not coated with the conductive ceramic coating.

17. The chuck of claim 10, wherein the chuck comprises a plurality of electrically conductive isolated dots sufficiently close to each other to allow rapid identification of a probe pin electrical parameter.

18. The chuck of claim 10, wherein the window comprises at least one of a diamond or diamond-like carbon.

19. A method of forming a chuck for holding a probe card under test by an integrated probe card analyzer, comprising:
forming a window in the chuck; and
at least partially coating the chuck with a conductive ceramic material.

20. The method of claim 19, wherein at least partially coating the chuck with a conductive ceramic material comprises sputtering the conductive ceramic material on the chuck.
